(19) United States
(12) Patent Application Publication
(10) Pub. No.: US 2026/0003020 A1
(43) Pub. Date: Jan. 1, 2026

(54) TEST FIXTURE, CALIBRATION SETUP AND METHOD OF CALIBRATING A TEST AND/OR MEASUREMENT INSTRUMENT

(71) Applicant: Rohde & Schwarz GmbH & Co. KG, Muenchen (DE)

(72) Inventors: Benedikt LIPPERT, Muenchen (DE); Martin PESCHKE, Muenchen (DE)

(21) Appl. No.: 18/757,040

(22) Filed: Jun. 27, 2024

(51) Int. Cl. G01R 35/00; G01R 1/04; G01R 31/319

(52) U.S. Cl. CPC G01R 35/005; G01R 1/0416; G01R 31/3191; G01R 35/002

(57) ABSTRACT

The present disclosure relates to a test fixture for being connected to a calibration device for calibrating a test and/or measurement instrument. The test fixture includes a probing point configured to receive a calibration signal while being in contact with a probe. The test fixture has a memory configured to store fixture data related to the probing point. Further, a calibration setup and a method of calibrating a test and/or measurement instrument are described.

### FIELD OF THE DISCLOSURE

Embodiments of the present disclosure relate to a test fixture for being connected to a calibration device for calibrating a test and/or measurement instrument. Further, embodiments of the present disclosure relate to a calibration setup and a method of calibrating a test and/or measurement instrument.

### BACKGROUND

For accurate measurements with a test and/or measurement instrument, for instance an oscilloscope, involved cables, fixtures and probes need to be corrected for a flat frequency response. Accordingly, a respective calibration is necessary in order to obtain the desired flat frequency response.

Current available solutions require an elaborate setup with multiple reconnections during the calibration procedure or require additional measurement equipment like a vector network analyzer. The reconnections are prone for errors, resulting in an inaccurate calibration such that the calibration has to be repeated. Consequently, the efforts and the costs are high for performing the calibration of the test and/or measurement instrument in a reliable and accurate manner.

Accordingly, there is a need for a simpler and more cost-efficient possibility to calibrate the test and/or measurement instrument.

### SUMMARY

The following summary of the present disclosure is intended to introduce different concepts in a simplified form that are described in further detail in the detailed description provided below. This summary is neither intended to denote essential features of the present disclosure nor shall this summary be used as an aid in determining the scope of the claimed subject matter.

Embodiments of the present disclosure relate to a test fixture for being connected to a calibration device for calibrating a test and/or measurement instrument. In an embodiment, the test fixture comprises a probing point configured to receive a calibration signal while being in contact with a probe. The test fixture has a memory configured to store fixture data related to the probing point.

Accordingly, the test fixture itself has a memory for storing information about the test fixture itself, namely the fixture data. The test fixture may be specific for a probe to be used with the test fixture, namely the probe that contacts the probing point provided by the test fixture. In addition, the test fixture receives the calibration signal that can be probed by the probe contacting the probing point.

An aspect provides that the test fixture comprises, for example, a signal interface configured to receive the calibration signal from the calibration device. In an embodiment, the calibration device may generate the calibration signal that is forwarded to the test fixture for being probed by a probe that contacts the probing point. Accordingly, a defined signal, namely the calibration signal, is generated and provided for being probed, thereby enabling to determine any disturbances introduced by determining deviations from the calibration signal.

Another aspect provides that the test fixture comprises, for example, a memory interface such that the memory of the test fixture is connectable to the calibration device. In an embodiment, the fixture data stored in the memory can be read out or accessed by the calibration device that is connected with the memory interface. Therefore, the calibration device is enabled to generate the calibration signal by taking the fixture data into account which is indicative of the test fixture and, thus, the probe to be used—as the test fixture may be specific for the probe.

Further, the fixture data may comprise calibration data which can be read out by the calibration device for generating the calibration signal. The calibration data is used for generating the calibration signal to be outputted by the calibration device while taking the fixture data into account, namely information about the test fixture.

For instance, the calibration data comprises data of frequency response, time delay, skew and/or scattering parameters. The respective data/information may be determined at factory site and stored in the memory. Hence, a user-friendly approach is provided since it is not necessary to characterize the test fixture for obtaining the data/information.

Generally, the fixture data can be determined during manufacturing of the test fixture. The fixture data obtained may also be stored in a cloud and when needed downloaded and stored in respective memory of the test fixture.

Embodiments of the present disclosure also provide a calibration setup. In an embodiment, the calibration setup comprises a calibration device for calibrating a test and/or measurement instrument. The calibration device comprises at least one fixture interface via which at least one test fixture is connectable with the calibration device. The calibration device comprises a processing circuit connected with the at least one fixture interface. The calibration device is configured to output a calibration signal to the at least one fixture interface.

Generally, the calibration device provides a known signal that is forwarded to the entire system connected with the calibration device, e.g. the measurement system used afterwards for testing/measuring a device under test. Therefore, the calibration device provides an easy and convenient usage without high efforts for building the calibration setup comprising cables, adapters and test fixtures. Moreover, the calibration device provides a “one time connect”-approach such that several reconnections of the cabling are not necessary, thereby improving the precision/accuracy. In an embodiment, the errors associated with the several reconnections can be avoided. Consequently, the calibration device makes the calibration of the test and/or measurement instrument simple and convenient and more accurate as the calibration is less prone to failures/errors.

In an embodiment, the at least one fixture interface may be a coaxial interface. Hence, the signal interface of the test fixture is also a coaxial interface, as the test fixture is connected with the fixture interface via its signal interface. Alternatively, the at least one fixture interface and the signal interface may be a universal serial bus, USB, interface.

According to a further alternative, the calibration device and the test fixture may be proprietary interfaces. For instance, the calibration device may have only one proprietary interface wherein the test fixture also has only one proprietary interface. Hence, the proprietary interfaces may be used for signal transmission and data exchange simultaneously.

An aspect provides that the calibration device has a signal source, for example, that is configured to generate a signal that is processed internally to obtain the calibration signal. In an embodiment, the signal source may be an arbitrary wave generator, AWG. Generally, the signal provided by the signal source may be a step signal, an impulse, a sine signal or a multi-tone signal. The signal source may be controlled by the processing circuit in order to generate/output the signal that is processed further for obtaining the calibration signal.

According to another aspect the calibration signal, for example, is configured to reduce at least one unwanted behavior of a test fixture connected with the at least one fixture interface. Hence, the fixture data provided by the memory of the test fixture may be taken into account by the calibration device, for example the processing circuit, such that effects introduced by the test fixture are compensated. In other words, characteristics of the test fixture are considered when generating the calibration signal, e.g. when processing the signal generated/provided by the signal source in order to obtain the calibration signal.

In an embodiment, the calibration device may be configured to apply a pre-distortion and/or a delay for generating the calibration signal. The pre-distortion may be introduced to compensate distortion of the subsequent test fixture connected with the calibration device. In a similar manner, any delay may be compensated.

A further aspect provides that the calibration device comprises, for example, an internal memory configured to store data based on which the calibration signal is generated. In an embodiment, the memory may inter alia store characterization data to be used for the calibration signal. Moreover, information about an external clock signal received can be stored, for instance a clock signal of the test and/or measurement instrument. Consequently, the calibration device is synchronized with the test and/or measurement instrument.

Alternatively or additionally, the calibration device comprises an internal clock generator configured to generate a clock signal. Hence, the calibration device is driven by its internal clock.

According to a further aspect, the calibration setup comprises, for example, at least one test fixture connected with the calibration device. In an embodiment, the at least one test fixture has a probing point configured to receive the calibration signal while being in contact with a probe. The at least one test fixture has a memory configured to store fixture data related to the probing point. The test fixture may relate to the one described above. Therefore, reference is made to the explanations given above. The calibration device interacts with the test fixture that is connected with the at least one fixture interface.

In an embodiment, the calibration device has a data interface configured to exchange data between the calibration device and the memory of the at least one test fixture. The data interface may relate to a universal serial bus, USB, interface. Generally, data such as the fixture data stored in the memory can be exchanged easily via the data interface.

For instance, the calibration device may automatically detect the test fixture connected to the calibration device, for example its fixture interface, by gathering the fixture data from the memory of the test fixture.

In an embodiment, the calibration setup may comprise a first test fixture and a second test fixture which are connected with a first fixture interface and a second fixture interface of the calibration device. The first test fixture has a first probing point configured to receive a respective first calibration signal while being in contact with a first probe as well as a first memory configured to store first fixture data related to the first probing point. The second test fixture has a second probing point configured to receive a respective second calibration signal while being in contact with a second probe as well as a second memory configured to store second fixture data related to the second probing point. Consequently, two calibration signals may be generated by the calibration device which are forwarded to two different test fixtures contacted by two different probes.

In an embodiment, the calibration setup may comprise a test fixture kit that encompasses more than two test fixtures that are selectively connectable with the calibration device. Different test fixtures may be provided wherein a user may select the test fixture to be used for calibrating the test and/or measurement instrument. The different test fixtures may be associated with the probes to be used by the test and/or measurement instrument.

Another aspect provides that the calibration setup additionally comprises, for example, a test and/or measurement instrument connected with the calibration device. Hence, the test and/or measurement instrument can be calibrated by providing the calibration signal to the probing point of the test fixture, which is used for calibrating the test and/or measurement instrument.

A further aspect provides that at least information about the calibration signal generated by the calibration device, for example, is forwarded to the test and/or measurement instrument. Consequently, the test and/or measurement instrument is aware of the calibration signal such that the test and/or measurement instrument is enabled to determine deviations from the intended calibration signal, thereby identifying effects introduced by the setup, e.g. the cable(s), probe(s) and/or components of the channel in general.

In an embodiment, at least one probe may be connected with the test and/or measurement instrument. The at least one probe probes the calibration signal forwarded to the probing point of the test fixture. Therefore, the probed signal corresponds to the calibration signal processed by the components of the setup, e.g. the cable(s), probe(s) and/or components of the channel in general.

For instance, the test and/or measurement instrument is an oscilloscope.

Generally, the calibration device provides a known signal, namely the calibration signal. The calibration signal is provided to the components of the system, e.g. the components of the calibration setup, which are also used later when performing measurements. These components relate to test fixture(s), cable(s) and probe(s). The test and/or measurement instrument measures (via the components) the processed calibration signal which may relate to a deteriorated signal. Further, the test and/or measurement instrument receives information about the calibration signal. With the knowledge of the characteristics of the calibration signal, the impact of the components, namely the cable(s) and/or probe(s), can be corrected.

The impact of the test fixture(s) may be compensated by the calibration device already, namely when generating the calibration signal. For this purpose, the memory of the respective test fixture(s) can be accessed in order to obtain the fixture data.

Alternatively, the impact of the test fixture(s) may also be corrected by the test and/or measurement instrument. The respective fixture data may be forwarded to the test and/or measurement instrument via the calibration device.

Embodiments of the present disclosure also relate to a method of calibrating a test and/or measurement instrument. In an embodiment, the method comprises:
Connecting a calibration device to the test and/or measurement instrument to be calibrated, wherein the calibration device comprises at least one fixture interface,
Connecting at least one text fixture to the at least one fixture interface of the calibration device, wherein the at least one text fixture comprises a probing point,
Connecting at least one probe with the test and/or measurement instrument, wherein the at least one probe contacts the probing point of the at least one text fixture,
Starting a calibration setup of the test and/or measurement instrument, and
Outputting a calibration signal by the calibration device, wherein the calibration signal is forwarded to the probing point of the at least one text fixture via the at least one fixture interface such that the calibration signal is probed by the at least one probe

The method ensures that the test and/or measurement instrument can be calibrated by a “one time connect”-approach while the calibration device provides the calibration signal to the probing point at which the probe connected with the test and/or measurement instrument contacts the test fixture for probing the calibration signal. The calibration signal or at least information about the calibration signal is forwarded to the test and/or measurement instrument such that the test and/or measurement instrument is enabled to compare the probed signal with the (intended) calibration signal, thereby identifying any influence/impact of the components of the setup which are also used later when performing measurements of a device under test by a measurement system. The measurement system comprises the components of the calibration setup except for the calibration device.

An aspect provides that the calibration signal, for example, is generated by the calibration device such that at least one unwanted behavior of a test fixture connected with the at least one fixture interface is reduced. Accordingly, the impacts of the test fixture on the signal processing can be compensated by the calibration device already, as the calibration device may be aware of the characteristics of the test fixture(s) due to the data/information stored in the memory of the test fixture.

Furthermore, the calibration device may comprise an interface for being connected with the test and/or measurement instrument. This interface may be galvanically isolated from the processing circuit, the fixture interface(s) and the data interface(s).

Generally, embodiment of the present disclosure cover the following use cases, among others:
Frequency response (magnitude and phase) correction for a channel of the test and/or measurement instrument, e.g. for factory calibration and/or on-site user calibration; crosstalk correction (magnitude and phase) between channels of the test and/or measurement instrument; test and/or measurement instrument with a cable connected to its channels, e.g. to measure at a device under test removing negative impact of the cable (loss, reflections); test and/or measurement instrument with connected probe (solder in, single ended or differential, current probe), e.g. to correct an unknown probe, adapter, connection, or a modified tip; test and/or measurement instrument with connected high-voltage/high-current probe, e.g., to correct the frequency response using a broadband voltage/current signal with RMS value significantly lower than peak its value, for instance by low/adjustable duty cycle, to account for maximum permissible peak—and RMS input of the probe; fixture and/or (relative/absolute) frequency response (magnitude and phase) correction for test and/or measurement instrument with two or more cables (coaxial) connected to its channels, e.g. to measure at a device under test with a balanced coaxial output (HDMI); test and/or measurement instrument with two or more connected probes (solder-in, single-ended or differential, current probe), e.g. to make measurements where the timing between two probes is crucial (DDR Memory, voltage and current measurement for power measurement); test and/or measurement instrument setup to measure a differential signal, e.g. to measure and correct frequency response and common-mode rejection of differential measurement setup.

In an embodiment, the calibration device is configured to control polarity of the calibration signals, e.g. toe form a real differential/common mode signal provided at two probing points of the test fixtures. Moreover, a level and/or a duty cycle of the at least one calibration signal is controllable, e.g. for high-voltage measurements.

In an embodiment, the calibration device may comprise additional time domain reflectometry, TDR, outputs.

In addition, at least one voltage and/or current output is provided.

### DESCRIPTION OF THE DRAWINGS

The foregoing aspects and many of the attendant advantages of the claimed subject matter will become more readily appreciated as the same become better understood by reference to the following detailed description, when taken in conjunction with the accompanying drawings, wherein:

FIG. 1 schematically shows an overview of a calibration setup according to an embodiment of the present disclosure, which comprises a test fixture according to an embodiment of the present disclosure, and

FIG. 2 schematically shows an overview of a method of calibrating a test and/or measurement instrument according to an embodiment of the present disclosure.

### DETAILED DESCRIPTION

The detailed description set forth below in connection with the appended drawings, where like numerals reference like elements, is intended as a description of various embodiments of the disclosed subject matter and is not intended to represent the only embodiments. Each embodiment described in this disclosure is provided merely as an example or illustration and should not be construed as preferred or advantageous over other embodiments. The illustrative examples provided herein are not intended to be exhaustive or to limit the claimed subject matter to the precise forms disclosed.

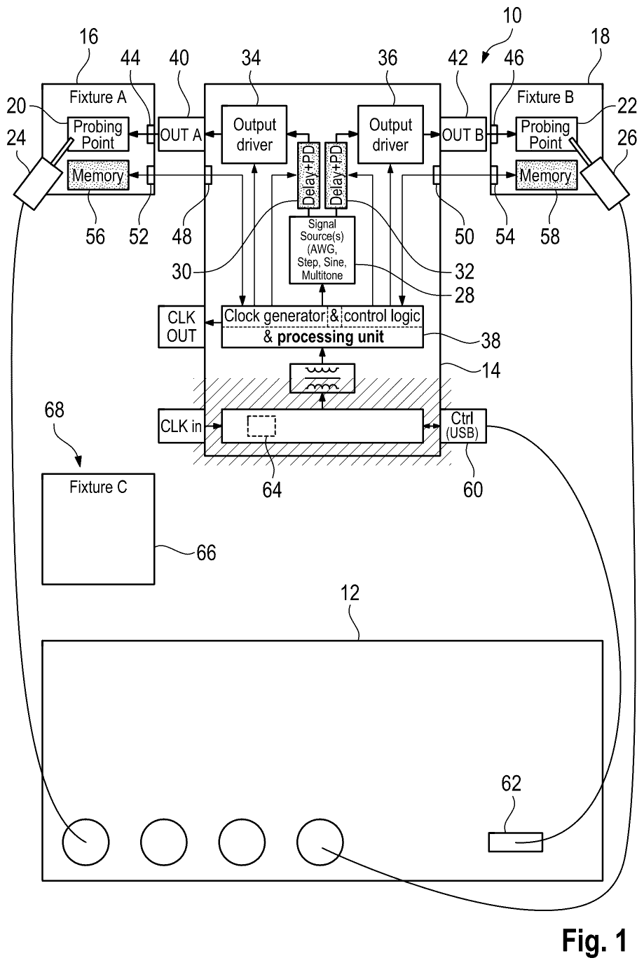

In FIG. 1, a calibration setup 10 according to an embodiment of the present disclosure is shown. As shown in FIG. 1, the setup 10 comprises a test and/or measurement instrument 12, e.g., an oscilloscope, and a calibration device 14 that is connected with two test fixtures 16, 18, namely a first test fixture 16 and a second test fixture 18. Each test fixture 16, 18 has a respective probing point 20, 22 for being contacted by a respective probe 24, 26. Accordingly, the first test fixture 16 has a first probing point 20 that is contacted by a first probe 24, whereas the second test fixture 18 has a second probing point 22 that is contacted by a second probe 26.

Both probes 24, 26 are connected with the test and/or measurement instrument 12 such that probed signals are forwarded to the test and/or measurement instrument 12 as will be explained later in more detail. In an embodiment, the signal probed by the probes 24, 26 relate to processed calibration signals that are generated by the calibration device 14, for example a signal source 28 of the test and/or measurement instrument 12.

In an embodiment, the signal source 28 provides/generates a signal that is forwarded to two modification circuits 30, 32, which apply a pre-distortion and/or a delay. The modified signals are forwarded to a respective output driver 34, 36.

In an embodiment, the calibration device 14 further comprises a processing circuit 38 that controls the signal source 28 and the output drivers 34, 36 so as to generate the first calibration signal and the second calibration signal which are forwarded to a first fixture interface 40 and a second fixture interface 42 to which the first test fixture 16 and the second test fixture 18 are connected, respectively.

The first test fixture 16 comprises a first signal interface 44 and the second test fixture 18 comprise a second signal interface 46 via which the respective test fixture 16, 18 is connected with the corresponding fixture interface 40, 42 of the calibration device 14 so as to receive the corresponding calibration signal. The signal interfaces 44, 46 are connected with the respective probing points 20, 22 such that the calibration signals can be probed by the probes 24, 26.

In an embodiment, the processing circuit 38 is further associated with a first data interface 48 and a second interface 50 which are connected to respective memory interfaces 52, 54 of the first test fixture 16 and the second test fixture 18, respectively. The first test fixture 16 and the second test fixture 18 both comprise a respective memory 56, 58.

In an embodiment, the memories 56, 58 are configured to store fixture data related to the corresponding probing point 20, 22 of the respective test fixture 16, 18. The fixture data comprises calibration data which can be read out by the calibration device 14, for example its processing circuit 38, for generating the calibration signal(s). The calibration data comprises data of frequency response, time delay, skew and/or scattering parameters of the respective test fixture 16, 18.

Based on the data accessed which is stored in the memories 56, 58, the impact of the respective test fixtures 16, 18 may be compensated by the calibration device 14 already, namely when generating the calibration signals that are forwarded to the probing points 20, 22. Hence, at least one unwanted behavior of the respective test fixture 16, 18 connected with the corresponding fixture interface 40, 42 is reduced.

Alternatively or additionally, the processing circuit 38 may communicate with a (galvanically isolated) interface 60 such that the fixture data accessed can be forwarded to the test and/or measurement instrument 12 having a corresponding interface 62, for instance a universal serial bus, USB, interface.

In an embodiment, the calibration device 14 may also comprise an internal memory 64 configured to store data based on which the calibration signal is generated. Hence, the processing circuit 38 may access the (galvanically isolated) internal memory 64 for gathering the data used for generating the calibration signal.

FIG. 1 further illustrates an additional test fixture 66 which can replace the first and second test fixtures 16, 18 already connected with the calibration device 14. Hence, the calibration setup 10 comprises a test fixture kit 68 having more than two test fixtures, namely the first test fixture 16, the second test fixture 18 and the additional test fixture 66, which are selectively connectable with the calibration device 14.

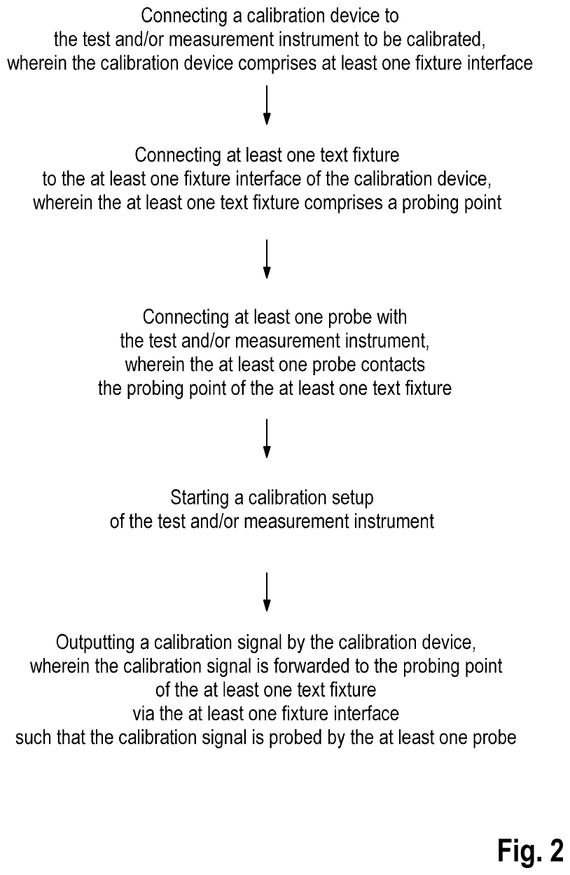

The calibration setup 10 shown in FIG. 1 can be obtained by performing the method, an example of which is illustrated in FIG. 2.

The calibration device 14 is connected to the test and/or measurement instrument 12 to be calibrated, wherein the calibration device 14 comprises at least one fixture interface 40, 42. At least one text fixture 16, 18 is connected to the respective fixture interface 40, 42 of the calibration device 14, wherein the respective text fixture 16, 18 comprises the respective probing point 20, 22. At least one probe 24, 26 is connected with the test and/or measurement instrument 12, wherein the at least one probe 24, 26 contacts the probing point 20, 22 of the respective text fixture 16, 18.

A calibration setup of the test and/or measurement instrument 12 is started. A calibration signal is outputted by the calibration device 14, wherein the calibration signal is forwarded to the probing point 20, 22 of the respective text fixture 16, 18 via the corresponding fixture interface 40, 42 such that the calibration signal is probed by the corresponding probe 24, 26.

The test and/or measurement instrument 12 receives the respective probed signal. In addition, the test and/or measurement instrument 12 knows the (intended) calibration signal(s) such that the impact of the components involved, namely the probe(s) 24, 26, the cable(s) and further components of the setup, can be determined. This can be done by comparing the probed signal(s) with the (intended) calibration signal(s) known.

As indicated above, the calibration signal(s) are/is generated such that any impact of the respective test fixture(s) 16, 18 is already compensated, wherein this is achieved by the fixture data stored in the corresponding memory 56, 58 accessed for reading out the data/information.

Certain embodiments disclosed herein include systems, apparatus, modules, units, devices, components, etc., that utilize circuitry (e.g., one or more circuits) in order to implement standards, protocols, methodologies or technologies disclosed herein, operably couple two or more components, generate information, process information, analyze information, generate signals, encode/decode signals, convert signals, transmit and/or receive signals, control other devices, etc. Circuitry of any type can be used. It will be appreciated that the term “information” can be use synonymously with the term “signals” in this paragraph. It will be further appreciated that the terms “circuitry,” “circuit,” “one or more circuits,” etc., can be used synonymously herein.

In an embodiment, circuitry includes, among other things, one or more computing devices such as a processor (e.g., a microprocessor), a central processing unit (CPU), a graphics processing unit (GPU), a digital signal processor (DSP), an application-specific integrated circuit (ASIC), a field programmable gate array (FPGA), a system on a chip (SoC), or the like, or any combinations thereof, and can include discrete digital or analog circuit elements or electronics, or combinations thereof. In an embodiment, circuitry includes hardware circuit implementations (e.g., implementations in analog circuitry, implementations in digital circuitry, and the like, and combinations thereof).

In an embodiment, circuitry includes combinations of circuits and computer program products having software or firmware instructions stored on one or more computer readable memories that work together to cause a device to perform one or more protocols, methodologies or technologies described herein. In an embodiment, circuitry includes circuits, such as, for example, microprocessors or portions of microprocessor, that require software, firmware, and the like for operation. In an embodiment, circuitry includes an implementation comprising one or more processors or portions thereof and accompanying software, firmware, hardware, and the like.

For example, the functionality described herein can be implemented by special purpose hardware-based computer systems or circuits, etc., or combinations of special purpose hardware and computer instructions. Each of these special purpose hardware-based computer systems or circuits, etc., or combinations of special purpose hardware circuits and computer instructions form specifically configured circuits, machines, apparatus, devices, etc., capable of implementing the functionality described herein.

Of course, in an embodiment, two or more of these components, or parts thereof, can be integrated or share hardware and/or software, circuitry, etc. In an embodiment, these components, or parts thereof, may be grouped in a single location or distributed over a wide area. In circumstances where the components are distributed, the components are accessible to each other via communication links.

In an embodiment, one or more of the components, such as instrument 12, the calibration device 14, test fixtures 16, 18 and/or 66, etc., referenced above include circuitry programmed to carry out one or more steps of any of the methods disclosed herein. In an embodiment, one or more computer-readable media associated with or accessible by such circuitry contains computer readable instructions embodied thereon that, when executed by such circuitry, cause the component or circuitry to perform one or more steps of any of the methods disclosed herein.

In an embodiment, the computer readable instructions includes applications, programs, program modules, scripts, source code, program code, object code, byte code, compiled code, interpreted code, machine code, executable instructions, and/or the like (also referred to herein as executable instructions, instructions for execution, program code, computer program instructions, and/or similar terms used herein interchangeably).

In an embodiment, computer-readable media is any medium that stores computer readable instructions, or other information non-transitorily and is directly or indirectly accessible to a computing device, such as processor circuitry, etc., or other circuitry disclosed herein etc. In other words, a computer-readable medium is a non-transitory memory at which one or more computing devices can access instructions, codes, data, or other information. As a non-limiting example, a computer-readable medium may include a volatile random access memory (RAM), a persistent data store such as a hard disk drive or a solid-state drive, or a combination thereof. In an embodiment, memory can be integrated with a processor, separate from a processor, or external to a computing system.

Accordingly, blocks of the block diagrams and/or flowchart illustrations support various combinations for performing the specified functions, combinations of operations for performing the specified functions and program instructions for performing the specified functions. These computer program instructions may be loaded onto one or more computer or computing devices, such as special purpose computer(s) or computing device(s) or other programmable data processing apparatus(es) to produce a specifically-configured machine, such that the instructions which execute on one or more computer or computing devices or other programmable data processing apparatus implement the functions specified in the flowchart block or blocks and/or carry out the methods described herein. Again, it should also be understood that each block of the block diagrams and flowchart illustrations, and combinations of blocks in the block diagrams and/or flowchart illustrations, or portions thereof, could be implemented by special purpose hardware-based computer systems or circuits, etc., that perform the specified functions or operations, or combinations of special purpose hardware and computer instructions.

In the foregoing description, specific details are set forth to provide a thorough understanding of representative embodiments of the present disclosure. It will be apparent to one skilled in the art, however, that the embodiments disclosed herein may be practiced without embodying all of the specific details. In some instances, well-known process steps have not been described in detail in order not to unnecessarily obscure various aspects of the present disclosure.

Although methods and various embodiments thereof may have been described as performing sequential steps, the claimed subject matter is not intended to be so limited. As nonlimiting examples, the described steps need not be performed in the described sequence and/or not all steps are required to perform the method. Moreover, embodiments are contemplated in which various steps are performed in parallel, in series, and/or a combination thereof. As such, one of ordinary skill will appreciate that such examples are within the scope of the claimed embodiments.

In the detailed description herein, references to “one embodiment”, “an embodiment”, “an example embodiment”, etc., indicate that the embodiment described may include a particular feature, structure, or characteristic, but every embodiment May not necessarily include the particular feature, structure, or characteristic. Moreover, such phrases are not necessarily referring to the same embodiment. In addition, when a particular feature, structure, or characteristic is described in connection with an embodiment, it is submitted that it is within the knowledge of one skilled in the art to affect such feature, structure, or characteristic in connection with other embodiments whether or not explicitly described. After reading the description, it will be apparent to one skilled in the relevant art(s) how to implement the disclosure in alternative embodiments. Thus, it will be appreciated that embodiments of the present disclosure may employ any combination of features described herein. All such combinations or sub-combinations of features are within the scope of the present disclosure.

Throughout this specification, terms of art may be used. These terms are to take on their ordinary meaning in the art from which they come, unless specifically defined herein or the context of their use would clearly suggest otherwise.

The drawings in the FIGURES are not to scale. Similar elements are generally denoted by similar references in the FIGURES. For the purposes of this disclosure, the same or similar elements may bear the same references. Furthermore, the presence of reference numbers or letters in the drawings cannot be considered limiting, even when such numbers or letters are indicated in the claims.

The present application may reference quantities and numbers. Unless specifically stated, such quantities and numbers are not to be considered restrictive, but exemplary of the possible quantities or numbers associated with the present application. Also in this regard, the present application may use the term “plurality” to reference a quantity or number. In this regard, the term “plurality” is meant to be any number that is more than one, for example, two, three, four, five, etc. The terms “about,” “approximately,” “near,” etc., mean plus or minus 5% of the stated value. For the purposes of the present disclosure, the phrase “at least one of A and B” is equivalent to “A and/or B” or vice versa, namely “A” alone, “B” alone or “A and B.”. Similarly, the phrase “at least one of A, B, and C,” for example, means (A), (B), (C), (A and B), (A and C), (B and C), or (A, B, and C), including all further possible permutations when greater than three elements are listed.

The principles, representative embodiments, and modes of operation of the present disclosure have been described in the foregoing description. However, aspects of the present disclosure which are intended to be protected are not to be construed as limited to the particular embodiments disclosed. Further, the embodiments described herein are to be regarded as illustrative rather than restrictive. It will be appreciated that variations and changes may be made by others, and equivalents employed, without departing from the spirit of the present disclosure. Accordingly, it is expressly intended that all such variations, changes, and equivalents fall within the spirit and scope of the present disclosure, as claimed.

The invention claimed is:

1. A test fixture for being connected to a calibration device for calibrating a test and/or measurement instrument, the test fixture comprising:
a probing point configured to receive a calibration signal while being in contact with a probe; and
a memory configured to store fixture data related to the probing point.

2. The test fixture according to claim 1, further comprising a signal interface configured to receive the calibration signal from the calibration device.

3. The test fixture according to claim 1, further comprising a memory interface such that the memory of the test fixture is connectable to the calibration device.

4. The test fixture according to claim 1, wherein the fixture data comprises calibration data which can be read out by the calibration device for generating the calibration signal.

5. The test fixture according to claim 4, wherein the calibration data comprises data of frequency response, time delay, skew and/or scattering parameters.

6. A calibration setup, comprising
a calibration device for calibrating a test and/or measurement instrument, wherein the calibration device comprises:
at least one fixture interface via which at least one test fixture is connectable with the calibration device;
a processing circuit connected with the at least one fixture interface,
wherein the calibration device is configured to output a calibration signal to the at least one fixture interface.

7. The calibration setup according to claim 6, wherein the calibration device has a signal source that is configured to generate a signal that is processed internally to obtain the calibration signal.

8. The calibration setup according to claim 6, wherein the calibration signal is configured to reduce at least one unwanted behavior of a test fixture connected with the at least one fixture interface.

9. The calibration setup according to claim 6, wherein the calibration device is configured to apply a pre-distortion and/or a delay for generating the calibration signal.

10. The calibration setup according to claim 6, wherein the calibration device comprises an internal memory configured to store data based on which the calibration signal is generated and/or wherein the calibration device comprises an internal clock generator configured to generate a clock signal.

11. The calibration setup according to claim 6, further comprising at least one test fixture connected with the calibration device, wherein the at least one test fixture has a probing point configured to receive the calibration signal while being in contact with a probe, and wherein the at least one test fixture has a memory configured to store fixture data related to the probing point.

12. The calibration setup according to claim 11, wherein the calibration device has a data interface configured to exchange data between the calibration device and the memory of the at least one test fixture.

13. The calibration setup according to claim 6, further comprising a first test fixture and a second test fixture which are connected with a first fixture interface and a second fixture interface of the calibration device, and wherein each test fixture has a probing point configured to receive a respective calibration signal while being in contact with a probe as well as a memory configured to store fixture data related to the probing point.

14. The calibration setup according to claim 6, further comprising a test fixture kit that encompasses more than two test fixtures that are selectively connectable with the calibration device.

15. The calibration setup according to claim 6, further comprising a test and/or measurement instrument connected with the calibration device.

16. The calibration setup according to claim 15, wherein at least information about the calibration signal generated by the calibration device is forwarded to the test and/or measurement instrument.

17. The calibration setup according to claim 15, wherein at least one probe is connected with the test and/or measurement instrument.

18. The calibration setup according to claim 15, wherein the test and/or measurement instrument is an oscilloscope.

19. A method of calibrating a test and/or measurement instrument, wherein the method comprises the steps of:
connecting a calibration device to the test and/or measurement instrument to be calibrated, wherein the calibration device comprises at least one fixture interface,
connecting at least one text fixture to the at least one fixture interface of the calibration device, wherein the at least one text fixture comprises a probing point,
connecting at least one probe with the test and/or measurement instrument, wherein the at least one probe contacts the probing point of the at least one text fixture,
starting a calibration setup of the test and/or measurement instrument, and
outputting a calibration signal by the calibration device, wherein the calibration signal is forwarded to the probing point of the at least one text fixture via the at least one fixture interface such that the calibration signal is probed by the at least one probe.

20. The method according to claim 19, wherein the calibration signal is generated by the calibration device such that at least one unwanted behavior of a test fixture connected with the at least one fixture interface is reduced.
